(19) United States
(12) Patent Application Publication
(10) Pub. No.: US 2026/0202879 A1
(43) Pub. Date: Jul. 16, 2026

(54) WATERPROOF POUCH FOR ELECTRONIC PRODUCTS

(71) Applicant: BENZHI (SHENZHEN) INFORMATION TECHNOLOGY CO., LTD., Shenzhen (CN)

(72) Inventors: Xihong Chen, Shenzhen (CN); Sihao Chen, Shenzhen (CN)

(21) Appl. No.: 19/071,737

(22) Filed: Mar. 5, 2025

(30) Foreign Application Priority Data
Jan. 13, 2025 (CN) 202520083212.4
Feb. 19, 2025 (CN) 202520274252.7

(51) Int. Cl. G06F 1/16; H05K 5/06

(52) U.S. Cl. CPC G06F 1/1656; H05K 5/069

(57) ABSTRACT

A waterproof pouch for electronic products includes a first casing, a second casing, an operating member, and a pouch body. The first casing includes two first locking parts thereon. The operating member includes an operating portion and two second locking parts. The second locking parts pass through the second casing and are rotatably connected to the first locking parts. An upper opening of the pouch body is sealed between the second casing and the first casing. Through the operating member to drive the two second locking parts, the operation is easy and quick.

### BACKGROUND OF THE INVENTION

### 1. Field of the Invention

The present invention relates to a waterproof pouch, and more particularly to a waterproof pouch for electronic products.

### 2. Description of the Prior Art

When people participate in water-related recreational activities such as rafting, swimming, water parks, etc. or use electronic products (such as mobile phones, tablets, etc.) outdoors on rainy days, water may enter electronic products, which results in damages to electronic products easily. For this reason, there are waterproof pouches for electronic products on the market, allowing people to carry and use electronic products conveniently. In order to facilitate people to use electronic products, view the contents of electronic products and capture scenes, the front of a conventional waterproof pouch is equipped with a transparent film facing the touchscreen of electronic products. Another transparent film, facing the camera of electronic products, is disposed on the back of the waterproof pouch. The front and the back of the waterproof pouch are sealed, thereby achieving the waterproofing of electronic products.

In the prior art, a pouch body is sealed by a sealing clip. The sealing clip includes a first casing and a second casing. The left and right ends of the first casing are provided with movable first locking members. The left and right ends of the second casing are provided with corresponding second locking members. Since the two first locking members are independently arranged, without any linkage between them, it is necessary to separately operate the first locking members at the left and right ends of the first casing, corresponding to the second locking members at the left and right ends of the second casing for sealing the pouch body. The operation is quite inconvenient.

Therefore, it is necessary to study a new technical solution to solve the above problems.

### SUMMARY OF THE INVENTION

In view of the deficiencies of the prior art, the primary object of the present invention is to provide a waterproof pouch for electronic products, which can solve the problem that it is inconvenient to operate the conventional waterproof pouches.

In order to achieve the above purpose, the present invention adopts the following technical solutions:

A waterproof pouch for electronic products comprises a first casing, a second casing, an operating member, and a pouch body.

The first casing includes two spaced first locking parts thereon.

The second casing and the first casing are connectable to each other.

The operating member includes an operating portion and two second locking parts that are disposed on the operating portion and matched with the first locking parts, respectively. The second locking parts pass through the second casing and are rotatably connected to the first locking parts. The operating member is selectively operated to be in a locked state or unlocked state.

An upper opening of the pouch body is sealed between the second casing and the first casing.

After the first casing and the second casing are connected to each other, the operating portion is turned for the two second locking parts to be simultaneously rotated and engaged with the respective first locking parts so that the operating member is in the locked state to prevent the first casing from being disconnected from the second casing and the upper opening of the pouch body is sealed. When the operating portion is turned for the two second locking parts to be simultaneously rotated and disengaged from the respective first locking parts, the operating member is in the unlocked state so that the first casing is disconnected from the second casing and the upper opening of the pouch body is open.

Compared with the prior art, the present invention has obvious advantages and beneficial effects.

Specifically, two spaced first locking parts are provided on the first casing. The operating member includes an operating portion and two second locking parts on the operating portion. When the operating portion is turned for the two second locking parts to be simultaneously rotated and engaged with the respective first locking parts, the operating member is in the locked state to prevent the first casing from being disconnected from the second casing, thereby sealing the waterproof pouch. Through the operating member to drive the two second locking parts, the operation is easy and quick.

Embodiments of the present invention will now be described, by way of example only, with reference to the accompanying drawings.

### BRIEF DESCRIPTION OF THE DRAWINGS

FIG. 1 is a perspective view of a waterproof pouch for electronic products according to a first embodiment of the present invention;

FIG. 2 is an exploded view of a sealing clip according to the first embodiment of the present invention;

FIG. 3 is another exploded view of the sealing clip according to the first embodiment of the present invention;

FIG. 4 is a further exploded view of the sealing clip according to the first embodiment of the present invention;

FIG. 5 is a cross-sectional view of the waterproof pouch for electronic products according to the first embodiment of the present invention, wherein the operating member is in a locked state;

FIG. 6 is a cross-sectional view of the waterproof pouch according to the first embodiment of the present invention, wherein the operating member is in an unlocked state;

FIG. 7 is an exploded view of the waterproof pouch for electronic products according to a second embodiment of the present invention, wherein the operating member is in an unlocked state;

FIG. 8 is another exploded view of the waterproof pouch for electronic products according to the second embodiment of the present invention, wherein the operating member is in an unlocked state;

FIG. 9 is an exploded view of the sealing clip according to a third embodiment of the present invention, wherein the operating member is in an unlocked state; and

FIG. 10 is another exploded view of the sealing clip according to the third embodiment of the present invention, wherein the operating member is in an unlocked state.

### DETAILED DESCRIPTION OF THE PREFERRED EMBODIMENTS

Spatially relative terms, such as “upper,” “lower,” “left,” “right,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. The device may be otherwise oriented (e.g., rotated 90 degrees or at other orientations) and the spatially relative descriptors used herein should be interpreted accordingly.

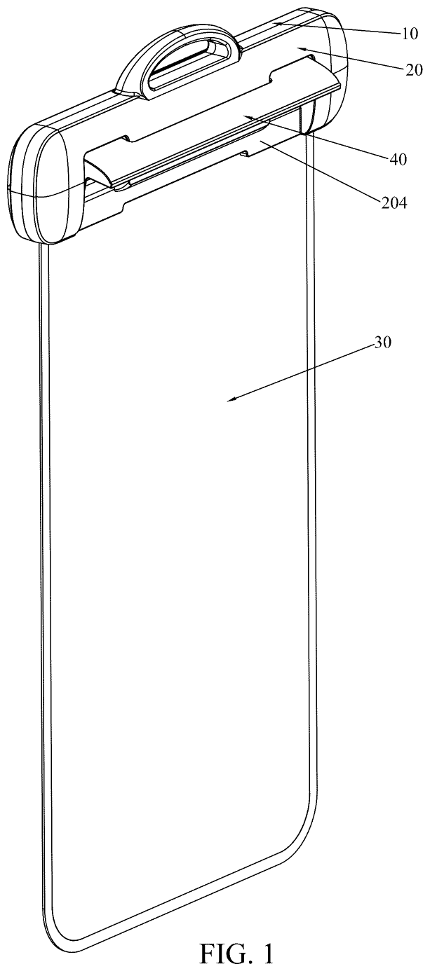

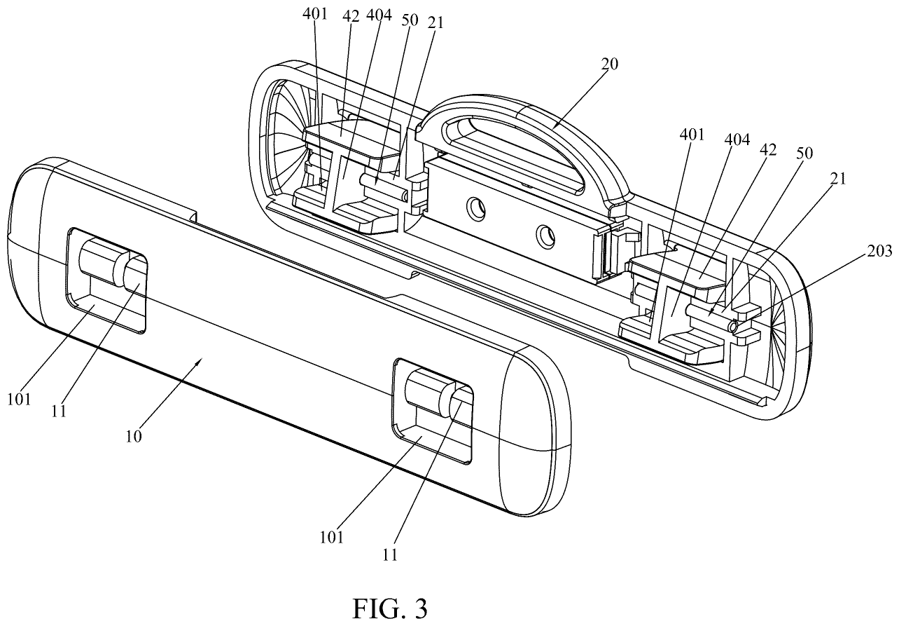

As shown in FIG. 1 through FIG. 6, a waterproof pouch for electronic products according to a first embodiment of the present invention comprises a first casing 10, a second casing 20, a pouch body 30, and an operating member 40. The first casing 10 and the second casing 20 are connectable to each other, forming a sealing clip for sealing the pouch body 30, so that the upper opening of the pouch body 30 can be sealed by the sealing clip.

Specifically, two spaced first locking parts 11 are provided on the first casing 10. The operating member 40 includes an operating portion 41 and two second locking parts 42 that are disposed on the operating portion 41 and matched with the first locking parts 11, respectively. The second locking parts 42 pass through the second casing 20 and are rotatably connected to the first locking parts 11. The operating member 40 is selectively operated to be in a locked state or unlocked state. After the first casing 10 and the second casing 20 are connected to each other, the operating portion 41 is turned for the two second locking parts 42 to be simultaneously rotated and engaged with the respective first locking parts 11 so that the operating member 40 is in the locked state to prevent the first casing 10 from being disconnected from the second casing 20. When the operating portion 41 is turned for the two second locking parts 42 to be simultaneously rotated and disengaged from the respective first locking parts 11, the operating member 40 is in the unlocked state so that the first casing 10 is disconnected from the second casing 20.

When the operating member 40 is in the unlocked state, after the first casing 10 and the second casing 20 are connected to each other, the operating portion 41 is turned for the two second locking parts 42 to be simultaneously rotated and engaged with the respective first locking parts 11, such that the second casing 20 and the first casing 10 are assembled together, thereby sealing the pouch body 30. Through the operating member 40 to drive the two second locking parts 42 simultaneously, the two second locking parts 42 can be locked to the two first locking parts 11 in one operation so that the operation is convenient and quick.

Specifically, two spaced second engaging members 21 are provided on the second casing 20. The first locking parts 11 are attached to the second engaging members 21. When the operating member 40 is turned, the second locking parts 42 slide along the outer walls of the second engaging members 21. Specifically, the second locking parts 42 have engaging grooves 401 to be in contact with the outer walls of the second engaging members 21. The first locking parts 11 are defined as first engaging members extending into the engaging grooves 401 to be in contact with the wall surfaces of the engaging grooves 401. When the operating member 40 is in the locked state, the wall surfaces of the engaging grooves 401 lean against the first engaging members and the first engaging members are confined in the engaging grooves 401 to prevent the first casing 10 from being disconnected from the second casing 20. When the operating member 40 is in the unlocked state, the wall surfaces of the engaging grooves 401 are disengaged from the first engaging members and the first engaging members are moved away from the engaging grooves 401, so that the first casing 10 is disconnected from the second casing 20.

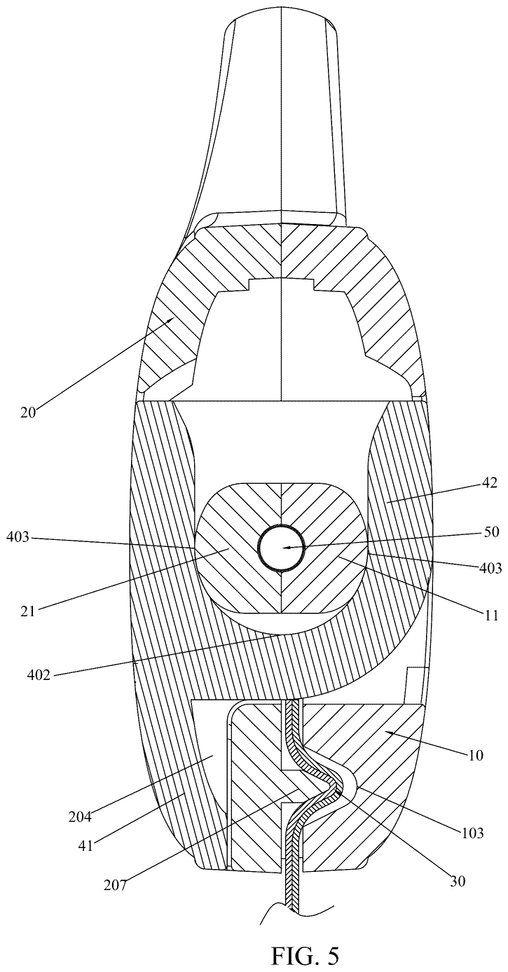

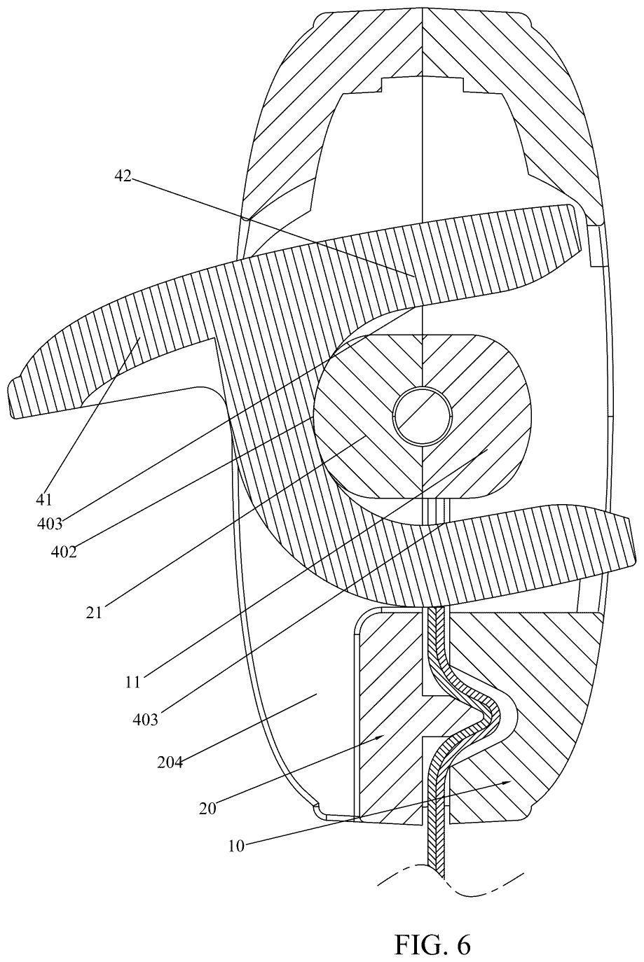

As an exemplary embodiment, the engaging grooves 401 each have an arc surface 402 and contact surfaces 403 connected to both ends of the arc surface 402. As shown in FIG. 5, when the operating member 40 is in the locked state, the contact surfaces 403 of the engaging grooves 401 jointly press the first engaging members against the second engaging members 21, ensuring a tight fit between the first casing 10 and the second casing 20. As shown in FIG. 6, when the operating member 40 is in the unlocked state, the outer walls of the second engaging members 21 are in contact with the arc surfaces 402 of the engaging grooves 401, and the contact surfaces 403 of the engaging grooves 401 are disengaged from the first engaging members, so that the first engaging members can be disengaged from the engaging grooves 401.

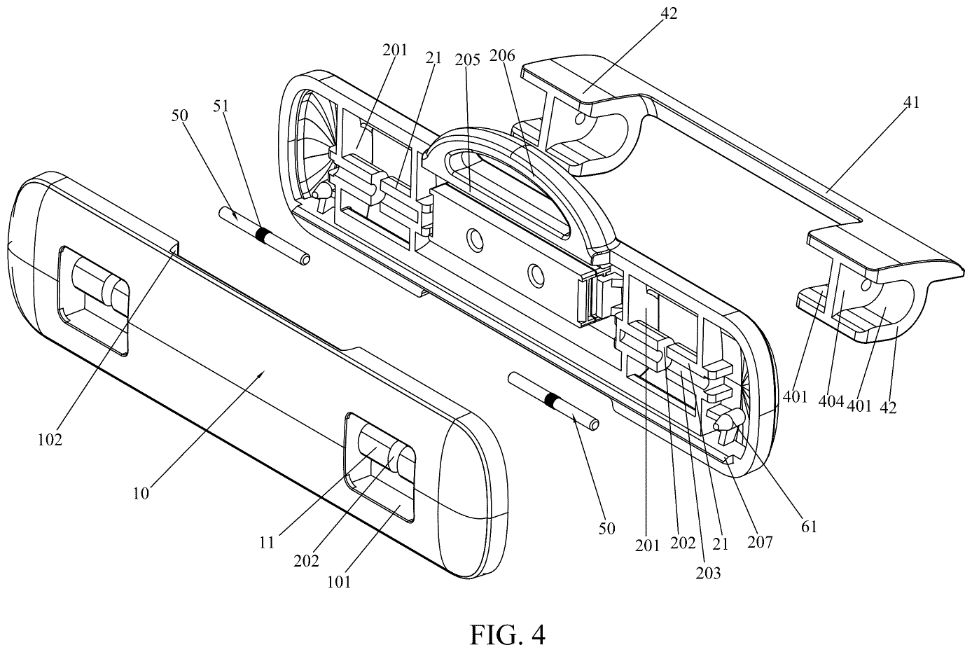

As shown in FIG. 4, the first casing 10 has two first through holes 101. The first engaging members are arranged transversely in the first through holes 101, respectively. The second casing 20 has two second through holes 201. The second engaging members 21 are arranged transversely in the second through holes 201, respectively. The second locking parts 42 pass through the first through holes 101 and the second through holes 201. Specifically, the second engaging members 21 and the first engaging members each have a second slot 202. An insertion plate 404 is provided in each of the engaging grooves 401. The insertion plate 404 passes through the second slot 202. A transverse rotating shaft 50 is insertedly connected to the insertion plate 404. Opposing sides of the first engaging members and the second engaging members 21 have receiving grooves 203. The rotating shaft 50 is rotatably located in the receiving grooves 203. When the operating member 40 is turned, the rotating shaft 50 is driven to rotate relative to the second engaging member 21. An anti-slip portion 51 is provided on the middle of the rotating shaft 50. The insertion plate 404 is fixedly connected to the rotating shaft 50 via the anti-slip portion 51.

The first engaging members and the second engaging members 21 are arranged transversely along the length direction of the first casing 10 and the second casing 20, and the two second locking parts 42 jointly lock the first engaging members, further improving the tight fit between the first casing 10 and the second casing 20. The insertion plate 404 is configured for increasing the structural strength of the second locking part 42, so that the second locking part 42 is less likely to deform during use, ensuring that the first casing 10 and the second casing 20 can be reliably, tightly fitted. The arrangement of the rotating shaft 50 prevents the operating member 40 from detaching from the second casing 20, thereby avoiding loss of the operating member 40, and enables the inner wall surfaces of the engaging grooves 401 to be in close contact with the outer wall surfaces of the second engaging members 21, thereby enhancing the friction between the inner wall surfaces of the engaging grooves 401 and the outer wall surfaces of the second engaging members 21. After the operating member 40 is turned to be in the unlocked state, the friction is used to keep the operating member 40 suspended in the unlocked state, facilitating the insertion of the first locking parts 11 into the engaging grooves 401. When the operating member 40 is turned to be in the locked state, the friction is used to keep the operating member 40 in the locked state.

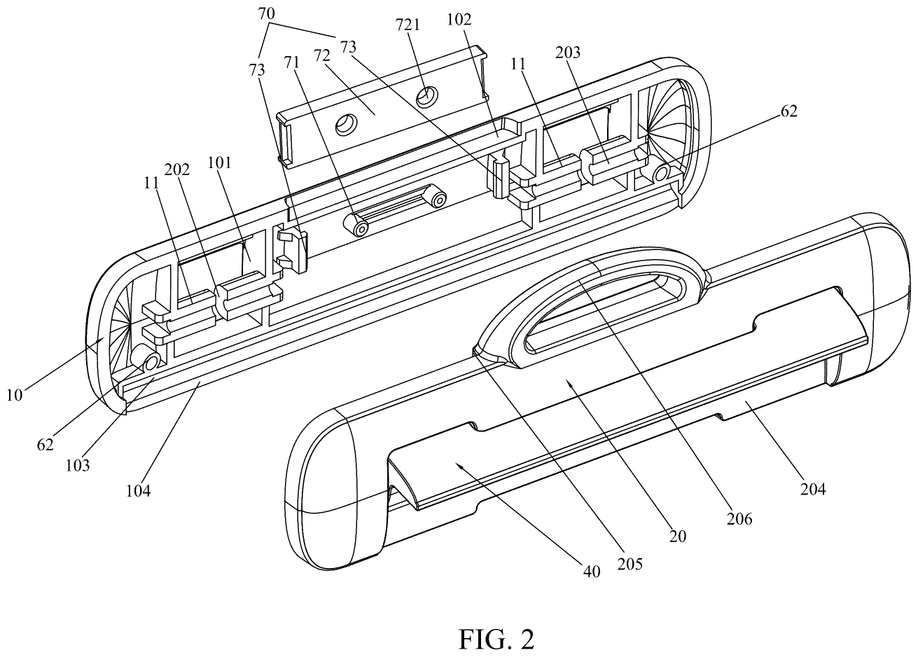

As shown in FIG. 2 and FIG. 5, the second casing 20 has an accommodating groove 204. When the operating member 40 is in the locked state, the operating member 40 is accommodated in the accommodating groove 204. The surface of the operating member 40 is flush with the opening of the accommodating groove 204, so that the operating portion 41 is in fit with the second casing 20, reducing the risk of accidental unlocking and enhancing the overall appearance.

As shown in FIG. 2 and FIG. 4, a protrusion 205 is provided on the upper end of the second casing 20 close to one side of the first casing 10. The top of the protrusion 205 and the top of the second casing 20 extend upward to form a lanyard hanging portion 206 for a rope to pass therethrough. The upper end of the first casing 10 has a notch 102 corresponding to the protrusion 205. When the first casing 10 and the second casing 20 are connected to each other, the protrusion 205 is inserted into the notch 102, such that the first casing 10 and the second casing 20 can be aligned and assembled together, enhancing accuracy and ease of assembly.

A first anti-detachment structure 60 is provided on the first casing 10 and/or the second casing 20 for securing both sides of the top of the pouch body. A second anti-detachment structure 70 is provided on the first casing 10 and the second casing 20 for securing the middle portion of the upper end of the pouch body.

As shown in FIG. 2 and FIG. 4, the first anti-detachment structure 60 includes first connecting posts 61 and connecting cylinders 62 for insertion of the first connecting posts 61. The first connecting posts 61 are located on two sides of the second casing 20. The connecting cylinders 62 are located on two sides of the first casing 10. The second anti-detachment structure 70 includes second connecting posts 71 passing through one side of the pouch body, a pressing plate 72, and two spaced engaging seats 73. The pressing plate 72 has receiving holes 721 corresponding to the second connecting posts 71. The pressing plate 72 is detachably connected between the two engaging seats 73 so that the second connecting posts 71 are inserted into the receiving holes 721.

Preferably, the end of the first connecting post 61 has a guide conical surface 611. The guide conical surface 611 facilitates the first connecting post 61 to pass through the pouch body. In this embodiment, the left and right sides of the upper end of the pouch body 30 have first connecting holes 301. The middle portion of the upper end of the pouch body 30 has second connecting holes 302. The second connecting holes 302 on the front and rear sides of the middle portion of the upper end of the pouch body are secured to the second connecting posts 71 of the first casing 10 and the second casing 20. After the first casing 10 and the second casing 20 are connected to each other, the two first connecting posts 61 pass through the first connecting holes 301 at the left and right sides of the upper end of the pouch body and are inserted into the connecting cylinders 62, thereby securing the left and right sides of the upper end of the pouch body and preventing the left and right sides of the upper end of the pouch body from being pulled out and improving the sealing performance.

As shown in FIG. 5 and FIG. 6, a pushing member 207 is provided on the lower end of the second casing 20, corresponding to one side of the first casing 10, for sealing the pouch body 30. The lower end of the first casing 10, corresponding to one side of the second casing 20, has a groove 103 to cooperate with the pushing member 207. The pushing member 207 can be inserted into the groove 103. When the pouch body 30 is clamped and secured between the first casing 10 and the second casing 20, the upper opening of the pouch body 30 is pushed into the groove 103 by the pushing member 207, thereby improving the sealing performance of the pouch body 30.

Referring to FIG. 2, a passageway 104 is disposed between the first casing 10 and the second casing 20 for the pouch body 30 to pass therethrough. Specifically, the passageway 104 is disposed on the first casing 10, so that the first casing 10 and the second casing 20 can fit tightly after being assembled.

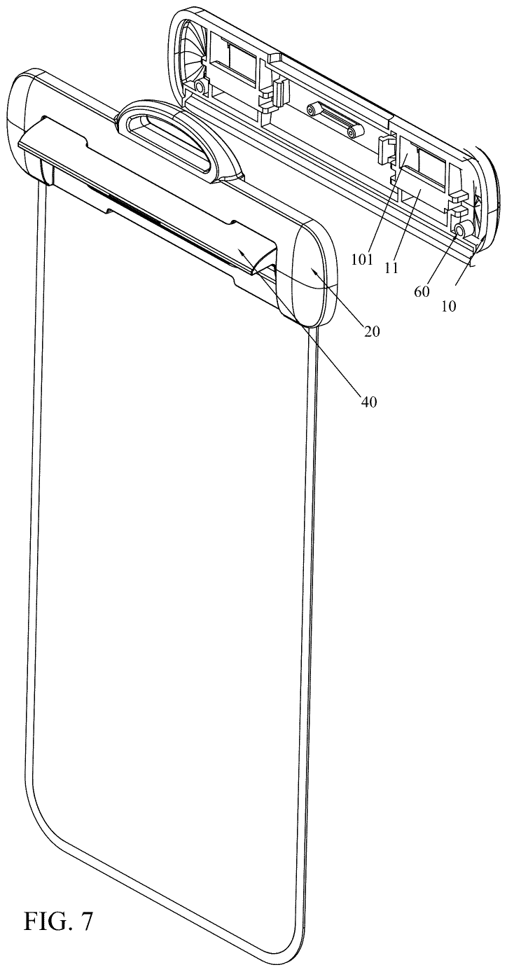

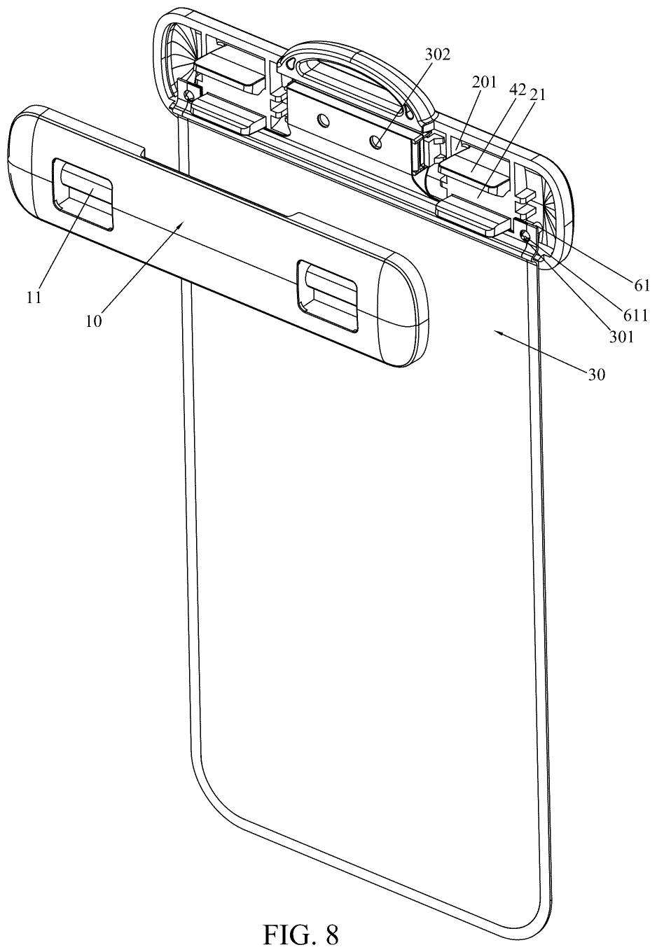

FIG. 7 and FIG. 8 illustrate a second embodiment of the present invention. The second embodiment is substantially similar to the first embodiment with the exceptions described hereinafter. In the second embodiment, the first engaging members and the second engaging members 21 don't have the second slot 202. That is, the operating member 40 is directly mounted on the second engaging members 21 through the second locking parts 42, so that the second locking parts 42 are rotated around the second engaging members 21. Thus, the operating member 40 is turned around the second engaging members 21 to be in the locked state or the unlocked state. The structure is simple.

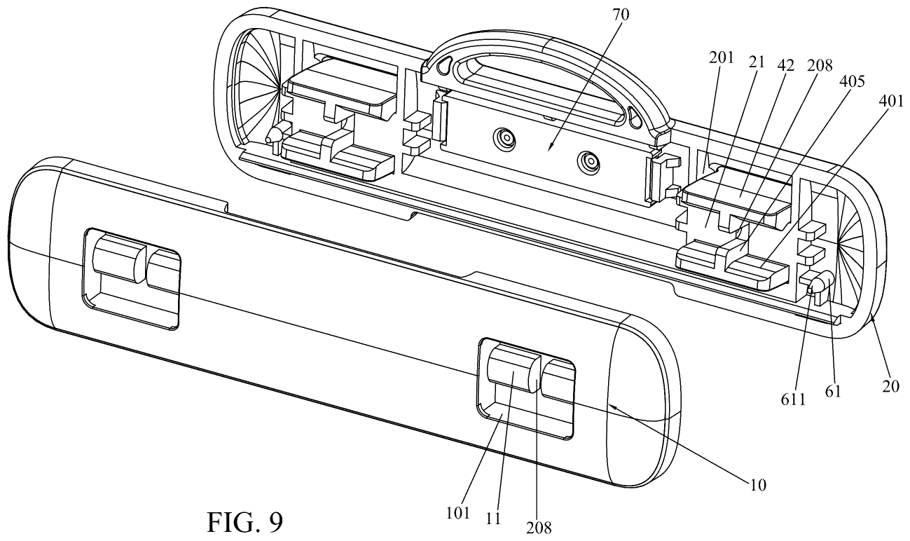

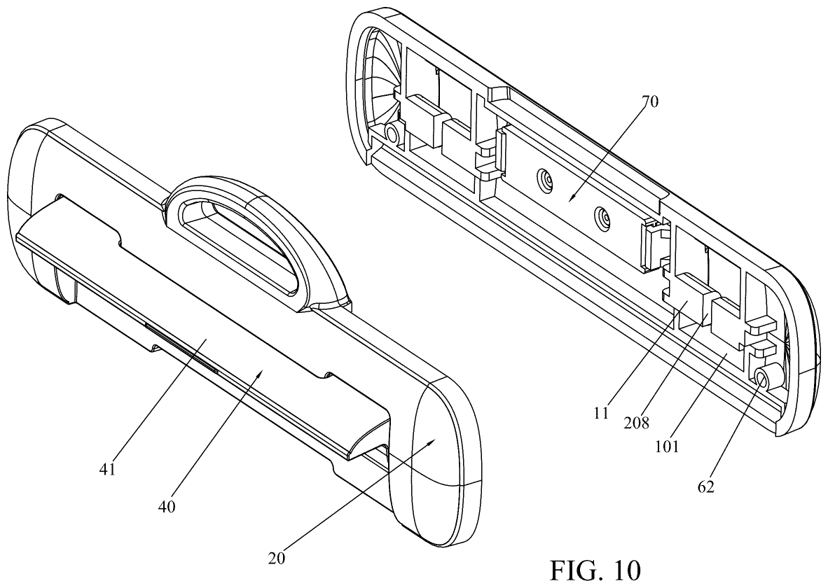

FIG. 9 and FIG. 10 illustrate a third embodiment of the present invention. The third embodiment is substantially similar to the first embodiment with the exceptions described hereinafter. In the third embodiment, reinforcing ribs 405 are provided on the wall surfaces of the engaging grooves 401 for enhancing the structural strength of the second locking parts 42. The first engaging members and the second engaging members 21 each have a first slot 208 for the reinforcing ribs 405 to pass therethrough. In this structure, there is a certain friction between the sides of the reinforcing ribs 405 and the second engaging members 21. After the operating member 40 is turned to be in the unlocked state, the friction is used to keep the operating member 40 suspended in the unlocked state, facilitating the insertion of the first locking parts 11 into the engaging grooves 401. When the operating member 40 is turned to be in the locked state, the friction is used to keep the operating member 40 in the locked state.

The features of the present invention are described below.

Firstly, two spaced first locking parts are provided on the first casing. The operating member includes an operating portion and two second locking parts on the operating portion. When the operating portion is turned for the two second locking parts to be simultaneously rotated and engaged with the respective first locking parts, the operating member is in the locked state to prevent the first casing from being disconnected from the second casing, thereby sealing the waterproof pouch. Through the operating member to drive the two second locking parts, the operation is easy and quick.

Secondly, the second locking parts have engaging grooves. The first locking parts are defined as first engaging members extending into the engaging grooves to be in contact with the wall surfaces of the engaging grooves. Two second engaging members are provided on the second casing. The operating portion is turned for the wall surfaces of the engaging grooves to lean against the first engaging members and the second engaging members, so as to seal the first casing and the second casing. The structure is cleverly designed.

Further, by providing the first anti-detachment structure, both sides of the upper end of the pouch body are secured to the first anti-detachment structure, thereby preventing both sides of the upper end of the pouch body from being pulled out after the pouch body is mounted to the sealing clip and improving the sealing performance.

Moreover, a protrusion is provided on the upper end of the second casing close to one side of the first casing. The top of the protrusion and the top of the second casing extend upward to form a lanyard hanging portion. The upper end of the first casing has a notch corresponding to the protrusion. Through the protrusion and the notch, the first casing and the second casing can be aligned and assembled accurately, enhancing accuracy and ease of assembly. The thickness of the lanyard hanging portion is increased, thereby improving the structural strength of the lanyard hanging portion. The structure is cleverly designed.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A waterproof pouch for electronic products, comprising:
a first casing, the first casing including two spaced first locking parts thereon;
a second casing, the second casing and the first casing being connectable to each other;
an operating member, the operating member including an operating portion and two second locking parts that are disposed on the operating portion and matched with the first locking parts respectively, the second locking parts passing through the second casing and being rotatably connected to the first locking parts, the operating member being selectively operated to be in a locked state or unlocked state;
a pouch body, an upper opening of the pouch body being sealed between the second casing and the first casing;
wherein after the first casing and the second casing are connected to each other, the operating portion is turned for the two second locking parts to be simultaneously rotated and engaged with the respective first locking parts so that the operating member is in the locked state to prevent the first casing from being disconnected from the second casing and the upper opening of the pouch body is sealed; when the operating portion is turned for the two second locking parts to be simultaneously rotated and disengaged from the respective first locking parts, the operating member is in the unlocked state so that the first casing is disconnected from the second casing and the upper opening of the pouch body is open.

2. The waterproof pouch for electronic products as claimed in claim 1, wherein a first anti-detachment structure is provided on the first casing and/or the second casing for securing two sides of an upper end of the pouch body.

3. The waterproof pouch for electronic products as claimed in claim 2, wherein left and right sides of the upper end of the pouch body have first connecting holes, the first anti-detachment structure includes first connecting posts passing through the first connecting holes and connecting cylinders for insertion of the first connecting posts, the first connecting posts are located on two sides of the second casing, and the connecting cylinders are located on two sides of the first casing.

4. The waterproof pouch for electronic products as claimed in claim 1, wherein a second anti-detachment structure is provided on the first casing and the second casing for securing a middle portion of an upper end of the pouch body, the middle portion of the upper end of the pouch body has second connecting holes, the second anti-detachment structure includes second connecting posts, a pressing plate and two spaced engaging seats, the pressing plate has receiving holes corresponding to the second connecting posts, the pressing plate is detachably connected between the two engaging seats, and the second connecting posts pass through the second connecting holes of one side of the pouch body and are inserted into the receiving holes.

5. The waterproof pouch for electronic products as claimed in claim 1, wherein a protrusion is provided on an upper end of the second casing close to one side of the first casing, and an upper end of the first casing has a notch corresponding to the protrusion.

6. The waterproof pouch for electronic products as claimed in claim 1, wherein the second locking parts have engaging grooves, the first locking parts are defined as first engaging members extending into the engaging grooves to be in contact with wall surfaces of the engaging grooves, the second casing includes two spaced second engaging members to be in contact with the wall surfaces of the engaging grooves;
when the operating member is in the locked state, the wall surfaces of the engaging grooves lean against the first engaging members and the first engaging members are confined in the engaging grooves, so as to prevent the first casing from being disconnected from the second casing; when the operating member is in the unlocked state, the wall surfaces of the engaging grooves are disengaged from the first engaging members, and the first engaging members are moved away from the engaging grooves so that the first casing is disconnected from the second casing.

7. The waterproof pouch for electronic products as claimed in claim 6, wherein the engaging grooves each have an arc surface and contact surfaces connected to two ends of the arc surface, when the operating member is in the locked state, the contact surfaces of the engaging grooves jointly press the first engaging members against the second engaging members, when the operating member is in the unlocked state, outer walls of the second engaging members are in contact with the arc surfaces of the engaging grooves.

8. The waterproof pouch for electronic products as claimed in claim 6, wherein the first casing has two first through holes, the first engaging members are arranged transversely in the first through holes respectively, the second casing has two second through holes, the second engaging members are arranged transversely in the second through holes respectively, and the second locking parts pass through the first through holes and the second through holes.

9. The waterproof pouch for electronic products as claimed in claim 6, wherein reinforcing ribs are provided on the wall surfaces of the engaging grooves, and the first engaging members and the second engaging members have first slots for the reinforcing ribs to pass therethrough.

10. The waterproof pouch for electronic products as claimed in claim 6, wherein an insertion plate is provided in each of the engaging grooves, the first engaging members and the second engaging members each have a second slot, the insertion plate is operated to pass through the second slot, a rotating shaft is insertedly connected to the insertion plate, opposing sides of the first engaging members and the second engaging members have receiving grooves, and the rotating shaft is rotatably located in the receiving grooves.
